(19) United States
(12) Patent Application Publication
(10) Pub. No.: US 2008/0130250 A1
(43) Pub. Date: Jun. 5, 2008

(54) Back plate

(75) Inventor: Ted Ju, Keelung City (TW)

Correspondence Address: TROXELL LAW OFFICE PLLC, SUITE 1404, 5205 LEESBURG PIKE, FALLS CHURCH, VA, 22041, US

(73) Assignee: Lotes co., Ltd.

(21) Appl. No.: 11/607,050

(22) Filed: Dec. 1, 2006

(51) Int. Cl. H05K 1/00

(52) U.S. Cl. 361/748

(57) ABSTRACT

A back plate serves to connect a circuit board. The back plate has an insulating body and a metal sheet. The metal sheet is installed on the insulating body having a strengthening function for the insulating body. The back plate with a metal sheet for strengthening the insulating body can not only reduce the weight of the back plate, but also enhance the strength of the back plate. Besides, the back plate has the advantages of simpler manufacture process and lower cost thereof.

### BACKGROUND OF THE INVENTION

(a) Field of the Invention

The present invention relates to back plates, in particular a back plate with a metal sheet.

(b) Description of the Prior Art

Due to demand of high speed information exchange of computer operations and computer operation time increasing more and more, a central processing unit of a computer produces more and more heat correspondingly. Therefore, a heat dissipating device of a computer is needed to dissipate the heat produced in the operation of a computer. When the heat dissipating device is installed on a motherboard, a back plate is needed to fix to the motherboard. Computer industries usually use two kinds of back plates now: one is a back plate made of plastics and the other is a back plate made of metal by press forging. Although the plastic back plate is manufactured simply and is needed a lower manufacture cost, the strength of the back plate is limited during the operating process. Sometimes, the plastic back plate cannot reach a strength standard so as to limit normal use thereof. Although the mental back plate has a higher strength durably which can reach the standard for normal use thereof, the mental back plate is heavier causing a computer heavier and manufacture costs thereof higher. Therefore, it is necessary to have a new style back plate so as to overcome the above-mentioned defects.

### SUMMARY OF THE INVENTION

The primary objective of the present invention is to provide a back plate. The back plate has several advantages, such as lower cost, simpler manufacture and lighter weight. The back plate can serve to connect a circuit board. The back plate has an insulating body and a metal sheet. The metal sheet is stalled cooperatively on the insulating body having a strengthening function for the insulating body.

To achieve above object, the present invention provides a back plate serving to connect a circuit board; comprising an insulating body and a metal sheet; and the insulating body being installed with an enhancing metal sheet.

### BRIEF DESCRIPTION OF THE DRAWINGS

FIG. 1 is a perspective exploded view of the back plate of the present invention.

FIG. 2 is a perspective assembled view of the back plate of the present invention.

FIG. 3 is a perspective view of the back plate of the second embodiment of the present invention.

FIG. 4 is a perspective view of the back plate of the third embodiment of the present invention.

FIG. 5 is a cross-sectional view of the A-A direction of FIG. 4.

FIG. 6 an assembled view of the back plate and the circuit board of FIG. 5.

### DETAILED DESCRIPTION OF THE PREFERRED EMBODIMENTS

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

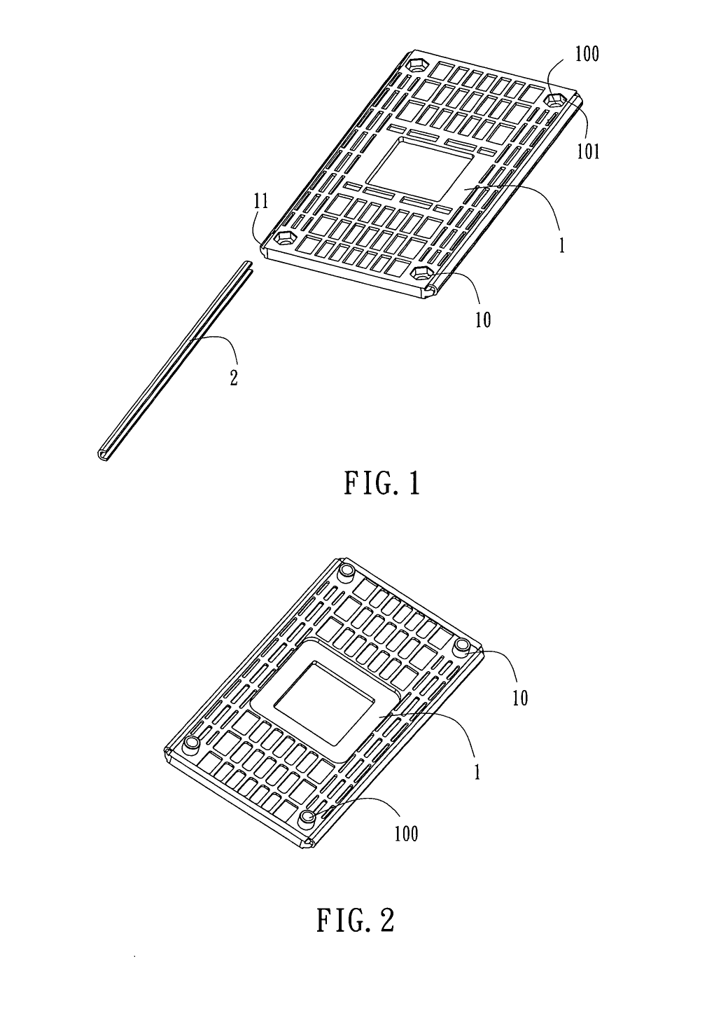

Referring to FIGS. 1 and 2, the back plate of the present invention has an insulating body 1 with a plate-shape and fixing devises 10 extending from the four corners of the insulating body 1 so as to connect to a circuit board (not shown). A metal sheet 2 is installed on and corresponding to the insulting body 1, having a strengthening function for the insulating body 1.

The metal sheet 2 is positioned on a lengthwise direction of the insulating body 1. The metal sheet 2 is formed as a U-shape (surely, the U-shape metal sheet 2 can be formed that the opening of the metal sheet 2 is smaller than the bottom). The U-shape metal sheet 2 is positioned on the two opposite sides of the insulating body 1. Matching portions 11 are installed on the insulating body 1 matching up the metal sheet 2. The matching portions 11 serve to connect firmly between the metal sheet 2 and the insulating body 1 having a function for strengthening the insulating body 1. The fixing devise 10 is a projection installed on the back plate. Besides, the projection extends out from a circuit board. A hole 100 of the projection serves to receive a screw nail (not shown). The other side of the projection has a receiving hole 101 serving to receive a female screw. The female screw (not shown) is received in the receiving hole 101. The matching screw nail (not shown) serves to fix a heat dissipating device (not shown) to the circuit board so as to achieve the firm connection between the heat dissipating device and the circuit board.

The two sides of back plate of the present invention have the metal sheet 2 having the function of strengthening thereof. The back plate has several advantages, such as a lower cost, a simpler manufacture process, and a lighter weigh. The back plate can guarantee to reach a strength requirement.

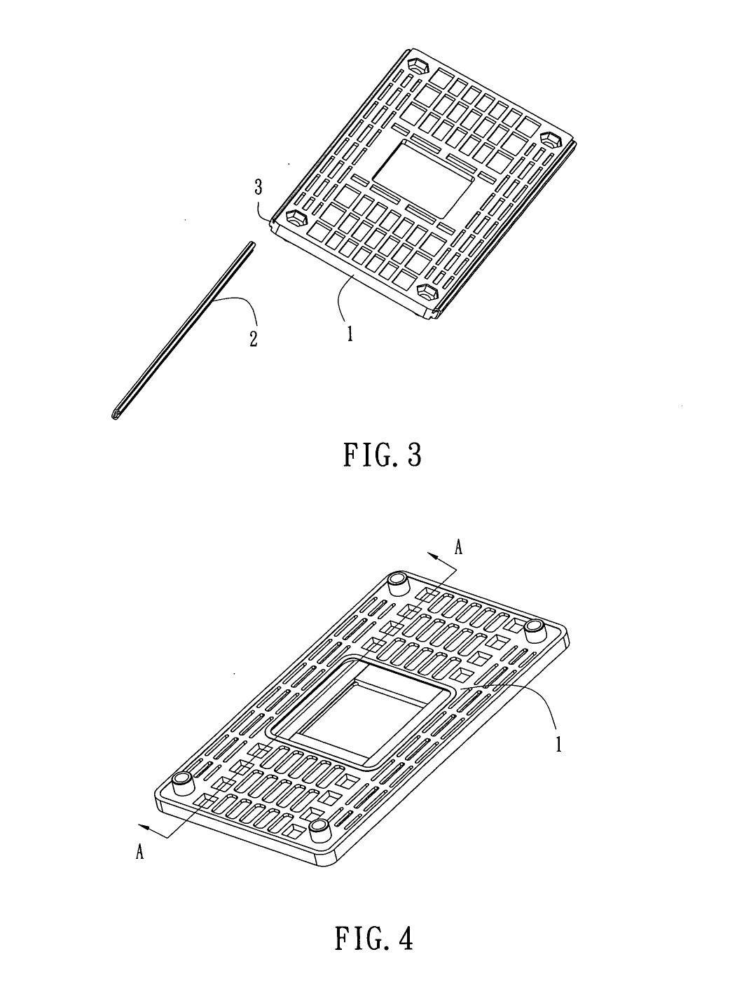

The second embodiment of the present invention is illustrated with FIG. 3. The differences between the second embodiment and the first embodiment are described as the followings. The metal sheet 2 is formed as a C-shape. A T-shape matching portion 3 extends from the insulating body 1 matching with the C-shape metal sheet 2. The second embodiment can achieve the same objective as the first embodiment.

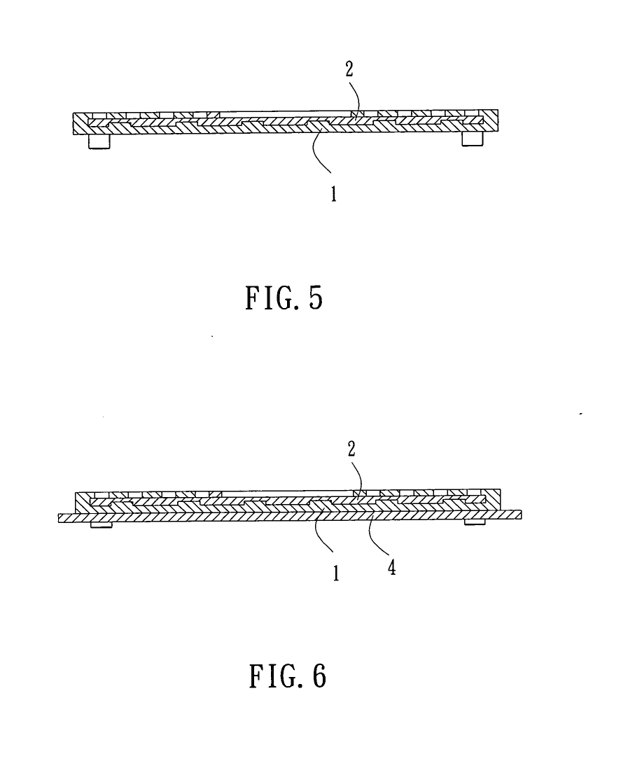

The third embodiment of the present invention is illustrated to FIGS. 4, 5 and 6. The differences between the third embodiment and the first embodiment are described as the followings. The metal sheet 2 is a integral body of the insulating body 1. Besides, the metal sheet 2 is buckled cooperatively with the insulating body 1 by having a protruding portion of the metal sheet 2 and a slot portion of the insulating body 1. The protruding portion protrudes out a circuit board 4. The third embodiment can achieve the same objective as the first embodiment.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A back plate serving to connect a circuit board; comprising an insulating body and a metal sheet; and the insulating body being installed with an enhancing metal sheet.

2. The back plate as claimed in claim 1, wherein the metal sheet is positioned on a lengthwise direction of the insulating body.

3. The back plate as claimed in claim 1, wherein the metal sheet is positioned on two opposite sides of the insulating body.

4. The back plate as claimed in claim 1, wherein the metal sheet is formed as a U-shape; and the opening of metal sheet is buckled to the insulating body.

5. The back plate as claimed in claim 1, wherein the metal sheet is formed as a C-shape.

6. The back plate as claimed in claim 5, wherein a T-shape matching potion extends from the insulating body and is matched to the C-shape metal sheet.

7. The back plate as claimed in claim 1, wherein the metal sheet is integrally formed with of the insulating body.

8. The back plate as claimed in claim 7, wherein the metal sheet is buckled to the insulating body by using a protruding portion of the metal sheet and a slot portion of the insulating body.

9. The back plate as claimed in claim 1, wherein a matching potion is formed on the insulating body for matching up with the metal sheet.

10. The back plate as claimed in claim 1, wherein a fixing device is installed on the insulating body matching up the circuit board; and the fixing devise protrudes out of the circuit board.
